(19) United States
(12) Patent Application Publication
(10) Pub. No.: US 2019/0067962 A1
(43) Pub. Date: Feb. 28, 2019

(54) MANAGEMENT DEVICE AND POWER SUPPLY DEVICE

(71) Applicant: SANYO Electric Co., Ltd., Daito-shi, Osaka (JP)

(72) Inventors: Tomoyuki Matsubara, Hyogo (JP); Kimihiko Furukawa, Hyogo (JP)

(73) Assignee: SANYO Electric Co., Ltd., Daito-shi, Osaka (JP)

(21) Appl. No.: 16/081,268

(22) PCT Filed: Feb. 20, 2017
(86) PCT No.: PCT/JP2017/006109

§ 371 Date: Aug. 30, 2018

(30) Foreign Application Priority Data
Mar. 15, 2016 (JP) 2016-050531

(51) Int. Cl. H02J 7/00; G01R 31/36

(52) U.S. Cl. CPC H02J 7/0026; G01R 31/3658

(57) ABSTRACT

A management device includes a voltage detection circuit and a plurality of capacitor circuits. The voltage detection circuit is connected, by voltage detection lines, to each node in a plurality of cells connected in series, to detect the voltage of each of the plurality of cells. The plurality of capacitor circuits are respectively connected to between two of the voltage detection lines which are respectively connected to the cells. The capacitor circuits corresponding to the adjacent two cells, have capacitance values different from each other.

### TECHNICAL FIELD

The present invention relates to a management device for managing a state of a power storage module including batteries, and a power supply device including the management device.

### BACKGROUND ART

In recent years, hybrid vehicles (HV), plug-in hybrid vehicles (PHV), and electric vehicles (EV) are being spread. Secondary batteries as a key device are installed in these vehicles. As secondary batteries for the vehicle, the nickel hydride batteries and the lithium ion batteries are spread. In the future, it is expected that spread of the lithium ion batteries having high energy density are accelerated.

Since the operable voltage range and the prohibited voltage range in the lithium ion batteries are close, the stricter voltage management is necessary in the lithium ion batteries than other types of batteries. When an assembled battery in which a plurality of the lithium ion battery cells are connected in series is used, a voltage detection circuit is provided for detecting each of the battery cells (for example, refer to Patent Literature 1). Between each of the battery cells and the voltage detection lines connected to the voltage detection circuit, at least one of a capacitance element for ESD (electro-static discharge) countermeasures and a capacitance element for a filter is connected. The voltage detected in each of the battery cells is used for controlling of charge or discharge, equalization in the cell voltages, or the like.

### CITATION LIST

### Patent Literature

Patent Literature 1: Unexamined Japanese Patent Publication No. 2001-116776

### SUMMARY OF THE INVENTION

### Technical Problems

Detecting disconnection of the voltage detection lines in the assembled battery, is an essential (indispensable) item in the failure detection in the system. However, when a certain voltage detection line is disconnected, the sum of the voltages of the two battery cells adjacent to this voltage detection line is divided by two capacitance elements each having an equal capacitance value. Thereby, the voltages which are supplied to the voltage detection circuit, are substantially the same as a case where the disconnection does not occur. Therefore, when the capacitance elements are connected at the voltage detection line, it is difficult that the disconnection is detected only by detecting the voltage of each of the battery cells.

The present invention has been conceived in light of such circumstances, and an object thereof is to provide a technique capable of more reliably detecting disconnection.

### Solution To Problem

To solve the above-mentioned requirements, a management device of one aspect of the present invention, includes:

voltage detection circuit which is connected, by voltage detection lines, to each node in a plurality of cells connected in series, for detecting a voltage of each of the plurality of cells; and

a plurality of capacitor circuits which are respectively connected to between two of the voltage detection lines which are respectively connected to the cells. The capacitor circuits corresponding to the adjacent two cells, have capacitance values different from each other.

### Advantageous Effects of Invention

According to the present invention, the disconnection can be more reliably detected.

### BRIEF DESCRIPTION OF DRAWINGS

FIG. 1 is a circuit diagram showing a power supply device according to one exemplary embodiment of the present invention.

FIG. 2(a) is a circuit diagram which shows the performance of charging in a case where voltage detection line L2 is disconnected in power supply device of FIG. 1. FIG. 2(b) is a graph which shows changes in the voltages of the circuit of FIG. 2(a). FIG. 2(c) is a circuit diagram which shows the performance of charging in a case where voltage detection line L2 is disconnected in a power supply device of a comparative example. FIG. 2(d) is a graph which shows changes in the voltages of the circuit of FIG. 2(c).

FIG. 3(a) is a circuit diagram which shows the performance of discharging in a case where voltage detection line L2 is disconnected in power supply device of FIG. 1. FIG. 3(b) is a graph which shows changes in the voltages of the circuit of FIG. 3(a). FIG. 3(c) is a circuit diagram which shows the performance of discharging in a case where voltage detection line L2 is disconnected in the power supply device of the comparative example. FIG. 3(d) is a graph which shows changes in the voltages of the circuit of FIG. 3(c).

### DESCRIPTION OF EMBODIMENTS

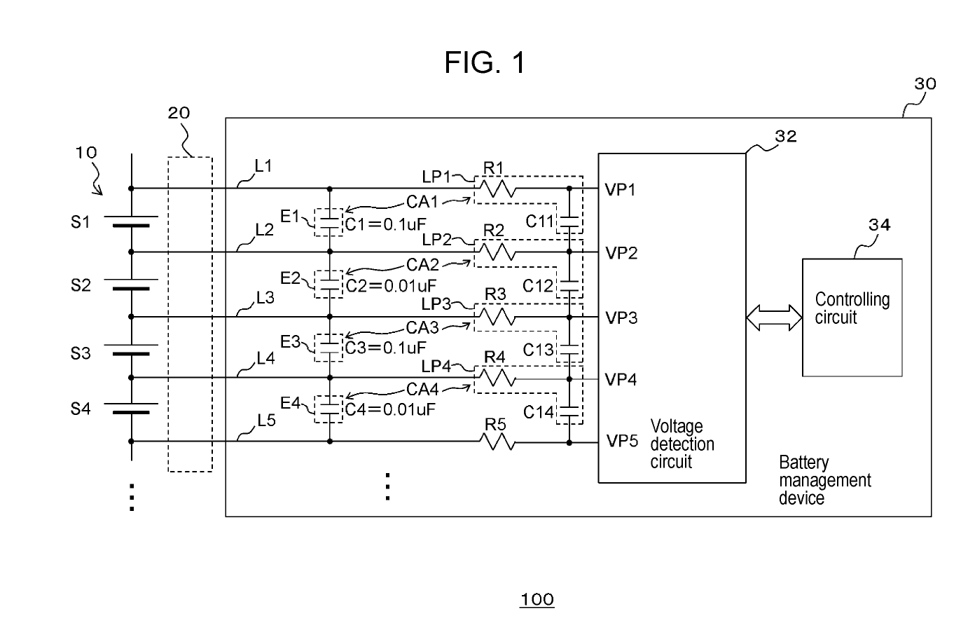

FIG. 1 is a circuit diagram showing a configuration of power supply device 100 according to one exemplary embodiment. Power supply device 100 is installed inside the vehicle, as a driving power source for hybrid vehicles(HV), or electric vehicles (EV). Power supply device 100 is provided with assembled battery (power storage module) 10 and battery management device (management device) 30. Assembled battery 10 and battery management device 30 are connected by wire harness 20.

Assembled battery 10 has a plurality of battery cells (cells) connected in series. In this exemplary embodiment, four pieces of battery cells S1-S4 are explained. However, explanations of other battery cells are omitted, and such other battery cells are not shown in figures. Herein, it is assumed to use lithium ion batteries as the battery cells. Assembled battery 10 which is installed inside the hybrid vehicle or electric vehicle, mainly has 200V or more. The battery cells are often connected in 60 or more series. A load and a charging circuit (not shown in figures) are connected between both ends of assembled battery 10. Assembled batter 10 is discharged to the load, and is charged with the charging circuit.

Battery management device 30 includes a plurality of capacitor circuits CA1-CA4, voltage detection circuit 32, and controlling circuit 34. The configuration corresponding to battery cells S1-S4 is explained, also in battery management device 30. However, explanations and figures of configurations corresponding to other battery cells are omitted. Battery management device 30 manages assembled battery 10. Battery management device 30, for example, is provided on a printed wiring board.

The nodes in the plurality of battery cells S1-S4 are respectively connected to a plurality of voltage input terminals VP1-VP5 of voltage detection circuit 32, by voltage detection lines L1-L5. Voltage detection lines L1-L5 are configured of, printed wirings inside battery management device 30, and wire harness 20 outside battery management device 30.

The plurality of capacitor circuits CA1-CA4 are respectively connected to between two of the voltage detection lines which are respectively connected to battery cells S1-S4. Namely, capacitor circuit CA1 is connected to between two voltage detection lines L1, L2 connected to battery cell S1. Capacitor circuits CA2-CA4 are also connected in the same way.

Each of the plurality of capacitor circuits CA1-CA4 includes an electrostatic discharge protection circuit which absorbs a discharge pulse caused by an electrostatic discharge, and a low pass filter circuit which has predetermined frequency characteristics. Namely, capacitor circuit CA1 includes electrostatic discharge protection circuit E1 and low pass filter circuit LP1. Capacitor circuits CA2-CA4 also have the same configuration.

Electrostatic discharge protection circuits E1-E4 respectively include first capacitance elements C1-C4. Each of the plurality of first capacitance elements C1-C4 is an ESD (Electro-Static Discharge) protection element. Therefore, the capacitance values of first capacitance elements C1-C4 is set as a value where the necessary electrostatic withstand voltage can be secured. The plurality of first capacitance elements C1-C4 are respectively connected to between two of the voltage detection lines which are respectively connected to battery cells S1-S4. In the example shown in FIG. 1, first capacitance element C1 is connected to between voltage detection line L1 and voltage detection line L2. In the same way, first capacitance element C2 is connected to between voltage detection line L2 and voltage detection line L3, and first capacitance element C3 is connected to between voltage detection line L3 and voltage detection line L4, and first capacitance element C4 is connected to between voltage detection line L4 and voltage detection line L5. Namely, the plurality of first capacitance elements C1-C4 are respectively connected to between both ends of the corresponding battery cells. First capacitance elements C1-C4 are disposed at the battery cells S1-S4 side, nearer than resistors R1-R5.

Two first capacitance elements C1, C2 corresponding to adjacent two battery cells S1, S2, have capacitance values different from each other. Two first capacitance elements C2, C3 corresponding to adjacent two battery cells S2, S3, have capacitance values different from each other. Two first capacitance elements C3, C4 corresponding to adjacent two battery cells S3, S4, have capacitance values different from each other. Thus, the electrostatic discharge protection circuits corresponding to the adjacent two battery cells, respectively have first capacitance elements which have capacitance values different from each other.

Herein, first capacitance elements C1, C3 corresponding to alternate battery cells S1, S3, may have a substantially equal capacitance value. First capacitance elements C2, C4 corresponding to alternate battery cells S2, S4, may have a substantially equal capacitance value. Since the capacitance elements have a substantially equal capacitance value, the hard ware can be commonized, and cost can be reduced.

As long as such a relationship is satisfied, the capacitance value is not limited specifically. For example, the capacitance value of first capacitance elements C1, C3 is about 0.1 μF, and the capacitance value of first capacitance elements C2, C4 is about 0.01 μF.

Voltage detection lines L1-L5 are respectively connected to the plurality of voltage input terminals VP1-VP5 of voltage detection circuit 32, through low pass filter circuits LP1-LP4. Low pass filter circuits LP1-LP4 suppress noises of voltage detection lines L1-L5. In the example shown in FIG. 1, the low pass filter is configured of an RC circuit. Concretely, each of low pass filter circuits LP1-LP4 includes a resistor and a second capacitance element. Resistors R1-R5 are respectively connected in series to voltage detection lines L1-L5. The plurality of second capacitance elements C11-C14 are respectively connected to between two of the voltage detection lines which are respectively connected to battery cells S1-S4, at the voltage detection circuit 32 side nearer than resistors R1-R5. Namely, second capacitance element C11 is connected to between voltage detection line L1 and voltage detection line L2. Second capacitance element C12 is connected to between voltage detection line L2 and voltage detection line L3. Second capacitance element C13 is connected to between voltage detection line L3 and voltage detection line L4. Second capacitance element C14 is connected to between voltage detection line L4 and voltage detection line L5. The resistance values of resistors R1-R5, are substantially equal. The capacitance values of second capacitance elements C11-C14, are substantially equal.

Thus, the two capacitor circuits corresponding to the adjacent two battery cells, have capacitance values different from each other. The capacitance value of capacitor circuit CA1, is the sum of the capacitance value of first capacitance element C1 and the capacitance value of second capacitance element C11. The capacitance values of capacitor circuits CA2-CA4 are in the same way. Herein, capacitor circuits CA1, CA3 corresponding to alternate battery cells S1, S3, may have a substantially equal capacitance value. Capacitor circuits CA2, CA4 corresponding to alternate battery cells S2, S4, may have a substantially equal capacitance value.

Voltage detection circuit 32 is connected to the nodes of battery cells S1-S4 connected in series, and detects each voltage of battery cells S1-S4. Concretely, voltage detection circuit 32 detects each voltage of voltage input terminals VP1-VP5. Each of detected voltages of battery cells S1-S4 is transmitted to controlling circuit 34. Voltage detection circuit 32 is configured of an ASIC (Application Specific Integrated Circuit) as the specific custom IC, or the like.

Controlling circuit 34 caries out battery controlling of equalizing control or the like, referring to obtained voltages from voltage detection circuit 32. In addition, when controlling circuit 34 detects the abnormality of the voltages of battery cells S1-S4, controlling circuit 34 notifies a higher rank controller (not shown in the figures) of an abnormal detection signal which shows the abnormality of the voltage. Further, when the higher rank controller is notified of the abnormal detection signal, the higher rank controller carries out a necessary countermeasure of stopping the charge and discharge of assembled battery 10 or the like. Concretely, in a case where any one of the voltages of battery cells S1-S4 is lower than first detection voltage UV or higher than second detection voltage OV, controlling circuit 34 outputs the abnormal detection signal. Second detection voltage OV is higher than first detection voltage UV. Controlling circuit 34 is configured of a CPU, a logic circuit, or their combination.

In this power supply device 100, in a case where the disconnection of any one of voltage detection lines L1-L5 occurs between battery cells S1-S4 and first capacitance elements C1-C4, the performance or operation is explained in the following. It is assumed that voltage detection line L2 is disconnected at wire harness 20. The following numerical values of voltages or the like are examples for explanations. The voltages are not limited to these numerical values.

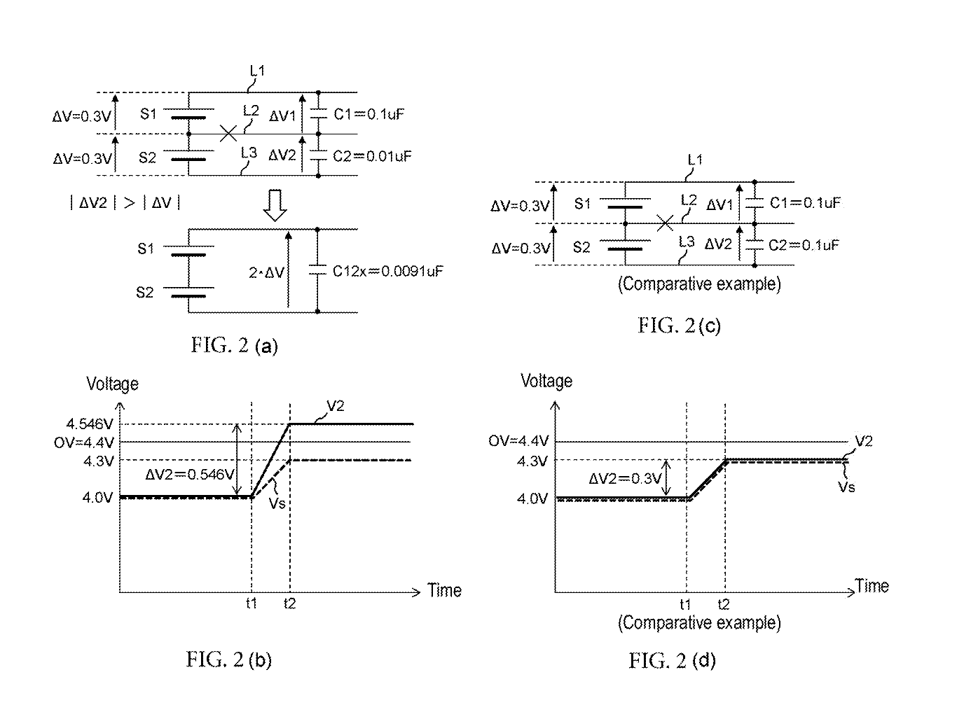

FIG. 2(a) is a circuit diagram which shows the performance of charging in a case where voltage detection line L2 is disconnected in power supply device 100 of FIG. 1. FIG. 2(b) is a graph which shows changes in the voltages of the circuit of FIG. 2(a). In FIG. 2(a), the circuit drawn at the upper portion of FIG. 2(a), shows only a part which relates to the following explanation within power supply device 100.The circuit drawn at the lower portion of FIG. 2(a), shows an equivalent circuit to the upper circuit. Capacitance element C12x is a combined capacitance of first capacitance elements C1 and C2.

As shown in FIG. 2(b), it is assumed that, voltages Vs of battery cells S1, S2 before charging are 4V, and the voltages Vs increases to 4.3V by charging from time t1 to t2. Namely, voltage change values ΔV of battery cells S1, S2 by charging are 0.3V.

Among two first capacitance elements C1 and C2 which are connected to disconnected voltage detection line L2, voltage change value ΔV2 by charging of first capacitance element C1 having a relatively small capacitance value, is larger than voltage change value ΔV1 by charging of first capacitance element C2 having a relatively large capacitance value. In the example of the numerical values shown in the figures, considering capacitance element C12x, ΔV1 is calculated as 0.0546V, and ΔV2 is calculated as 0.546V. Then, ΔV2 is larger than ΔV1.

Accordingly, as shown in FIG. 2(b), voltage V2 of both ends of first capacitance element C2, which is detected by voltage detection circuit 32 after time t2 subsequent to charging, is 4.546V which is higher than real voltage Vs (=4.3V) of battery cell S2. Second detection voltage OV is 4.4V.

Further, not shown in the figures, voltage V1 of both ends of first capacitance element C1, which is detected by voltage detection circuit 32 after time t2, is 4.0546V which is lower than real voltage Vs (=4.3V) of battery cell S1.

Thus, after charging assembled battery 10, even though voltages Vs of battery cells S1, S2 are lower than second detection voltage OV, voltage V2 of both ends of first capacitance element C2 having the small capacitance becomes higher than second detection voltage OV. Therefore, controlling circuit 34 can output the abnormal detection signal.

FIG. 2(c) is a circuit diagram which shows the performance of charging in a case where voltage detection line L2 is disconnected in a power supply device of a comparative example. FIG. 2(d) is a graph which shows changes in the voltages of the circuit of FIG. 2(c). As shown in FIG. 2(c), in the comparative example, capacitance values of a plurality of first capacitance elements are substantially equal. The other configurations are the same as this exemplary embodiment.

As shown in FIG. 2(d), since capacitance values of first capacitance elements C1, C2 are equal to each other, Voltage V2 of both ends of first capacitance element C2 after charging, is equal to voltage Vs of battery cells S2. Accordingly, the abnormal detection signal is not outputted at this timing. When voltages Vs of battery cells S1, S2 become different from each other by repeated charging and discharging, voltage V2 and voltage Vs of battery cell S2 are different. Then, voltage V1 is also different from voltage Vs of battery cell S1. Therefore, since voltages Vs of battery cells S1, S2 are not correctly detected, voltages Vs are not correctly controlled. Accordingly, when time elapses, there is a possibility that voltages Vs of battery cell S1, S2 become higher than second detection voltage OV.

In this exemplary embodiment, after an occurrence of the disconnection, the abnormal detection signal can be outputted before voltage Vs of battery cell S2 becomes higher than second detection voltage OV. Therefore, the necessary countermeasure of stopping the charge and discharge of assembled battery 10 or the like can be carried out earlier than the comparative example.

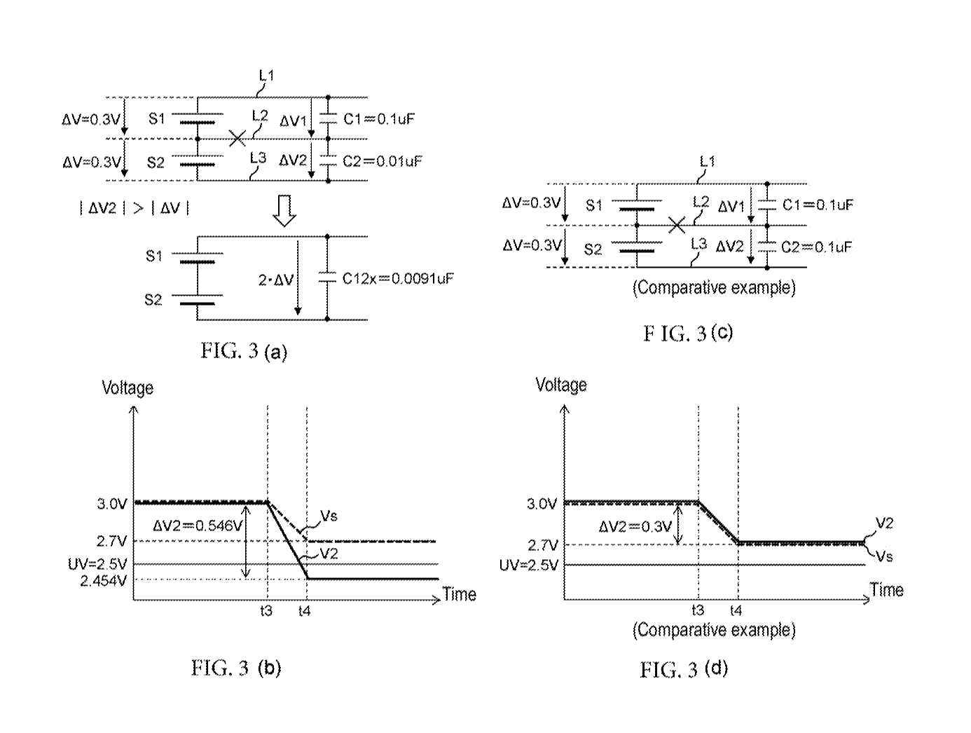

FIG. 3(a) is a circuit diagram which shows the performance of discharging in a case where voltage detection line L2 is disconnected in power supply device 100 of FIG. 1. FIG. 3(b) is a graph which shows changes in the voltages of the circuit of FIG. 3(a).

It is assumed that, voltages Vs of battery cells S1, S2 before discharging are 3V, and the voltages Vs decreases to 2.7V by discharging from time t3 to t4. Namely, voltage change values ΔV of battery cells S1, S2 by discharging are 0.3V.

Among two first capacitance elements C1 and C2 which are connected to disconnected voltage detection line L2, voltage change value ΔV2 by discharging of first capacitance element C1 having the small capacitance value, is larger than voltage change value ΔV1 by discharging of first capacitance element C2 having the large capacitance value. In the example of the numerical values shown in the figures, ΔV1 is calculated as 0.0546V, and ΔV2 is calculated as 0.546V. Then, ΔV2 is larger than ΔV1.

Accordingly, as shown in FIG. 3(b), voltage V2 of both ends of first capacitance element C2, which is detected by voltage detection circuit 32 after time t4 subsequent to discharging, is 2.454V which is lower than real voltage Vs (=2.7V) of battery cell S2. First detection voltage UV is 2.5V.

Thus, after discharging assembled battery 10, even though voltages Vs of battery cells S1, S2 are higher than first detection voltage UV, voltage V2 of both ends of first capacitance element C2 having the small capacitance becomes lower than first detection voltage UV. Therefore, controlling circuit 34 can output the abnormal detection signal.

As a difference between the capacitance value of first capacitance elements C1, C3 and the capacitance value of first capacitance elements C2, C4 becomes larger, the voltage change value by charging or discharging becomes larger at the time of an occurrence of the disconnection. Accordingly, the disconnection can be more reliably detected.

FIG. 3(c) is a circuit diagram which shows the performance of discharging in a case where voltage detection line L2 is disconnected in the power supply device of the comparative example. FIG. 3(d) is a graph which shows changes in the voltages of the circuit of FIG. 3(c).

As shown in FIG. 3(d), since capacitance values of first capacitance elements C1, C2 are equal to each other, Voltage V2 of both ends of first capacitance element C2 after discharging, is equal to voltage Vs of battery cells S2. Accordingly, the abnormal detection signal is not outputted at this timing. When time elapses, there is a possibility that voltages Vs of battery cell S1, S2 become lower than first detection voltage UV.

In this exemplary embodiment, after an occurrence of the disconnection, the abnormal detection signal can be outputted before voltage Vs of battery cell S2 becomes lower than first detection voltage UV. Therefore, the necessary countermeasure can be carried out earlier than the comparative example.

As explained above, according to this exemplary embodiment, in a case of an occurrence of the disconnection, by charging or discharging battery cells S1-S4, among the two first capacitance elements which are connected to the disconnected voltage detection line, the voltage change value of the first capacitance element having the small capacitance value, can be larger than voltage change value ΔV1 of the battery cell. Thus, controlling circuit 34 can output the abnormal detection signal. Accordingly, in the case where first capacitance elements C1-C4 are connected to between the voltage detection lines, the disconnection can be more reliably detected.

When the capacitance values of first capacitance elements C1-C4 as the ESD (Electro-Static Discharge) protection element are set as described above, battery management device 30 can be realized. Thus, it is not necessary that new circuit elements are added to the above-mentioned comparative example. Further, a consumption current of battery management device 30 is not increased, compared with the comparative example. Even though the capacitance value of first capacitance elements C1, C3 is different from the capacitance value of first capacitance elements C2, C4, it does not affect the performance of detecting the voltages in voltage detection circuit 32.

Since the capacitance values of first capacitance elements C1-C4 are two kinds, a cost increase can be suppressed, and making a manufacturing process complicated can be suppressed, compared with the comparative example in which one kind of the capacitance value of the first capacitance elements is used.

The present invention has been described based on the exemplary embodiment. A person of the ordinary skill in the art can understand that the exemplary embodiment is illustrative only, constitution elements and combined processes can be modified, and such modified examples are covered by the scope of the present invention.

In the above-mentioned exemplary embodiment, battery management device 30 is used for managing the secondary batteries for the vehicle. Battery management device 30 can be also used for managing power storage modules in a stationary power storage system. Additionally, capacitors, such as electric double layer capacitors can be used as battery cells S1-S4.

As long as the two first capacitance elements corresponding to the adjacent two battery cells, have capacitance values different from each other, the capacitance values of first capacitance elements C1-C4 are not specifically limited. For example, the first capacitance elements corresponding to every third battery cell, may have a substantially equal capacitance value. Further, each of the first capacitance elements may have a different capacitance value.

With respect to first capacitance elements C1-C4 as the ESD (Electro-Static Discharge) protection element, the two first capacitance elements corresponding to the adjacent two battery cells, have capacitance values different from each other, as explained above. On contrast, first capacitance elements C1-C4, may have a substantially equal capacitance value. different from each other, as explained above. Then, with respect to second capacitance elements C11-C14 constituting the low pass filter, the two second capacitance elements corresponding to the adjacent two battery cells, may have capacitance values different from each other. In this case, the cut-off frequencies of the plurality of low pass filters respectively are different from each other, and their capacitances are set so as to satisfy the frequency characteristics which can remove the noises.

Further the two first capacitance elements corresponding to the adjacent two battery cells, have capacitance values different from each other, and additionally, the two second capacitance elements corresponding to the adjacent two battery cells, may have capacitance values different from each other. In this case, considering the combined capacitance of the first and second capacitance elements corresponding to the one battery cell, two combined capacitances corresponding to the adjacent two battery cells can be different from each other.

The exemplary embodiment may be specified by items described below.

### [Item 1]

A management device (30) includes:

a voltage detection circuit (32) which is connected, by voltage detection lines (L1-L5), to each node in a plurality of cells (S1-S4) connected in series, to detect the voltage of each of the plurality of cells (S1-S4); and

a plurality of capacitor circuits (CA1 -CA4) which are respectively connected to between two of the voltage detection lines which are respectively connected to the cells (S1-S4).

The capacitor circuits (CA1 and CA2, CA2 and CA3, CA3 and CA4) corresponding to the adjacent two cells (S1 andS2, S2 and S3, S3 and S4) have capacitance values different from each other.

Accordingly, the disconnection can be more reliably detected.

### [Item 2]

In the management device (30) according to item 1,

the capacitor circuits (CA1 and CA3, CA2 and CA4) corresponding to every other cell (S1 and S3, S2 and S4), have a substantially equal capacitance value.

Accordingly, since the capacitance values of the capacitor circuits (CA1-CA4) are two kinds, a cost increase can be suppressed, and making a manufacturing process complicated can be suppressed.

### [Item 3]

In the management device (30) according to item 1 or 2,

each of the plurality of capacitor circuits (CA1-CA4) includes an electrostatic discharge protection circuit (E1-E4) which absorbs a discharge pulse caused by an electrostatic discharge, and a low pass filter circuit (LP1-LP4) which has predetermined frequency characteristics.

the two electrostatic discharge protection circuits (E1 and E2, E2 and E3, E3 and E4) corresponding to the adjacent two cells (S1 andS2, S2 and S3, S3 and S4), respectively have electro-static discharge protection elements (C1 and C2, C2 and C3, C3 and C4) which have capacitance values different from each other.

Accordingly, each of the low pass filter circuits (LP1-LP4) has the substantially equal frequency characteristics, and additionally, the two capacitor circuits (CA1 and CA2, CA2 and CA3, CA3 and CA4) have the capacitance values different from each other. Therefore, it does not affect the performance of detecting the voltages in the voltage detection circuit (32).

### [Item 4]

A power supply device (100) includes:

a power storage module (10) in which the plurality of cells (S1-S4) are connected in series; and

the management device (30) according to any one of items 1 to 3 to manage the power storage module (10).

Accordingly, the power supply device (100) can be provided where the disconnection can be more reliably detected.

### REFERENCE MARKS IN THE DRAWINGS

S1-S4 battery cell
L1-L5 voltage detection line
CA1-0A4 capacitor circuit
E1-E4 electrostatic discharge protection circuit
C1-C4 first capacitance element
LP1-LP4 low pass filter circuit
C11-C14 second capacitance element
R1-R5 resistor
10 assembled battery
30 battery management device
32 voltage detection circuit
34 controlling circuit
100 power supply device

1. A management device comprising:
voltage detection circuit which is connected, by voltage detection lines, to each node in a plurality of cells connected in series, for detecting a voltage of each of the plurality of cells; and
a plurality of capacitor circuits which are respectively connected to between two of the voltage detection lines which are respectively connected to the cells,
wherein the capacitor circuits corresponding to the adjacent two cells, have capacitance values different from each other.

2. The management device according to claim 1,
wherein the capacitor circuits corresponding to every other cell, have a substantially equal capacitance value.

3. The management device according to claim 1,
wherein each of the plurality of capacitor circuits includes an electrostatic discharge protection circuit which absorbs a discharge pulse caused by an electrostatic discharge, and a low pass filter circuit which has predetermined frequency characteristics, and
the two electrostatic discharge protection circuits corresponding to the adjacent two cells, respectively have electro-static discharge protection elements which have capacitance values different from each other.

4. A power supply device comprising:
a power storage module in which the plurality of cells are connected in series; and
the management device according to claim 1, for managing the power storage module.

5. The management device according to claim 2,
wherein each of the plurality of capacitor circuits includes an electrostatic discharge protection circuit which absorbs a discharge pulse caused by an electrostatic discharge, and a low pass filler circuit which has predetermined frequency characteristics, and
the two electrostatic discharge protection circuits corresponding to the adjacent two cells, respectively have electro-static discharge protection elements which have capacitance values different from each other.

6. A power supply device comprising:
a power storage module in which the plurality of cells are connected in series; and
the management device according to claim 2, for managing the power storage module.

7. A power supply device comprising:
a power storage module in which the plurality of cells are connected in series; and
the management device according to claim 3, for managing the power storage module.
